(19) United States
(12) Patent Application Publication
(10) Pub. No.: US 2024/0387199 A1
(43) Pub. Date: Nov. 21, 2024

(54) SEMICONDUCTOR PROCESS DEVICE AND GAS INLET APPARATUS

(71) Applicant: BEIJING NAURA MICROELECTRONICS EQUIPMENT CO., LTD., Beijing (CN)

(72) Inventor: Gang XU, Beijing (CN)

(21) Appl. No.: 18/291,988

(22) PCT Filed: Jul. 26, 2022
(86) PCT No.: PCT/CN2022/107878

§ 371 Date: Jan. 25, 2024

(30) Foreign Application Priority Data
Jul. 29, 2021 (CN) 202110864551.2

(51) Int. Cl. H01L 21/67

(52) U.S. Cl. CPC H01L 21/67017

(57) ABSTRACT

A gas inlet apparatus of a semiconductor process device for passing process gases into a process chamber, includes: a gas inlet block assembly and a connection assembly, both being made of anti-corrosion materials. The gas inlet block assembly is hermetically connected to an upper cover of the process chamber, a gas mixing chamber, a gas transport channel, and a gas mixing channel are formed in the gas inlet lock assembly, a gas inlet of the gas transport channel is connected to the gas mixing chamber, and a gas outlet of the gas transport channel is connected to the process chamber. The gas mixing channel includes a plurality of gas inlets being formed on an outer surface of the gas inlet block assembly, and a gas outlet of the gas mixing channel is connected to the gas mixing chamber.

### TECHNICAL FIELD

The present disclosure relates to the technical field of semiconductor technologies and, more particularly, to a semiconductor process device and a gas inlet apparatus.

### BACKGROUND

Currently, in an ammonia-hydrogen fluoride dry etching process, after entering a process chamber, a wafer is driven by a base to rise to a process position. A dilution gas is introduced into the process chamber to control the pressure of the process chamber. After the pressure in the process chamber reaches a process pressure and the temperature of the wafer rises to a process temperature, a reaction gas and the dilution gas are passed into the process chamber to presoak a surface of the wafer. The reaction gas includes, for example, ammonia gas (NH3) and hydrogen fluoride (HF). The two gases are mixed to form a highly active reactant ammonium fluoride (NH4F). Then, the reaction gas and the dilution gas are passed into the process chamber again, and at this time the reaction gas reacts with silicon dioxide on the surface of the wafer to generate solid by-products. Finally, the wafer is heat treated in an annealing chamber to vaporize the solid by-products, thereby achieving etching the surface of the wafer. During actual execution of the process, parameters such as the base platform temperature, the process pressure, a ratio of ammonia (NH3) and hydrogen fluoride (HF) in the reaction gas, a dilution gas flow, time intervals or task spacing, and temperature difference in the process chamber all will have an impact on uniformity and selectivity of finally etched wafer.

In a current process, the reaction gas and the dilution gas enter a mixing chamber through a mixing pipeline structure to be mixed, and then are introduced into the process chamber through a gas inlet pipe. During a gas intake process, corrosive reaction gases (such as hydrogen fluoride) will corrode the pipelines. Contaminants, such as iron (Fe), resulted from the corroded pipelines, may enter the process chamber and fall on the wafer. It is difficult to remove the contaminants. The contaminants may cause a particle index on the surface of the wafer to exceed a standard threshold, thereby significantly reducing wafer yield.

### SUMMARY

The present invention aims to solve at least one of the technical problems existing in the prior art, and provides a semiconductor process device and a gas inlet apparatus for solving the technical problems existing in the prior art that contaminants from the corroded gas inlet apparatus occurring in the process chamber reduce the wafer yield.

One aspect of the present disclosure provides a gas inlet apparatus of a semiconductor process device disposed at top of a process chamber of the semiconductor process device for passing process gases into the process chamber. The gas inlet apparatus includes a gas inlet block assembly and a connection assembly. Both are made of anti-corrosion materials. The gas inlet block assembly is hermetically connected to an upper cover of the process chamber, a gas mixing chamber, a gas transport channel, and a gas mixing channel are formed in the gas inlet lock assembly, a gas inlet of the gas transport channel is connected to the gas mixing chamber, and a gas outlet of the gas transport channel is connected to the process chamber. The gas mixing channel includes a plurality of gas inlets being formed on an outer surface of the gas inlet block assembly, and a gas outlet of the gas mixing channel is connected to the gas mixing chamber. The connection assembly includes a plurality of connection assemblies disposed on the gas inlet block assembly, the plurality of connection assemblies are connected to the plurality of gas inlets of the gas mixing channel in a one-to-one correspondence, the plurality of connection assemblies are used to connect to a plurality of process gas supply sources in a one-to-one correspondence, and each connection assembly is used to selectively introduce or stop the process gases into the gas mixing channel.

In some embodiments, the process gases include hydrogen fluoride; the gas inlet block assembly is made of anti-corrosion materials including aluminum; and the connection assembly is made of anti-corrosion materials including Hastelloy alloy.

In some embodiments, the gas inlet block assembly includes a first gas inlet block, a second gas inlet block, and a third gas inlet block that are hermetically connected in sequence, and the first gas inlet block is hermetically connected to the upper cover of the process chamber; the gas transport channel is formed in the first gas inlet block and the second gas inlet block, and the gas mixing chamber is formed between the second gas inlet block and the third gas inlet block; and the gas mixing channel is formed in the second gas inlet block and the third gas inlet block.

In some embodiments, the gas inlet apparatus further includes a temperature control component. The temperature control component is disposed in the first gas inlet block, the second gas inlet block, and the third gas inlet block for detecting temperatures of the first gas inlet block, the second gas inlet block, and the third gas inlet block.

In some embodiments, the gas transport channel includes a first gas transport branch and a second gas transport branch; the first gas transport branch includes a first vertical channel and a first horizontal channel that are formed in the first gas inlet block and are interconnected, the first vertical channel is arranged to extend in an axial direction of the process chamber, and the first horizontal channel is arranged to extend in a radial direction of the process chamber; a gas outlet of the first vertical channel is connected to the process chamber, and a gas inlet of the horizontal channel is connected to second gas transport branch; and the second gas transport branch includes two interconnected second horizontal channels that are formed in the second gas inlet block. The two second horizontal channels both are parallel to a radial cross-section of the process chamber, the two form an angle, a gas outlet of one of the two horizontal channels is connected to a gas inlet of the first horizontal channel, and a gas inlet of the other second horizontal channel is connected to the gas mixing chamber.

In some embodiments, a gas mixing groove is configured on at least one of two opposite-facing sealing surfaces of the third gas inlet block and the second gas inlet block to form the gas mixing chamber.

In some embodiments, the gas mixing channel includes a first gas mixing branch, a connection branch, and a plurality of second gas mixing branches; the first gas mixing branch includes a third horizontal channel and a fourth horizontal channel that are formed in the third gas inlet block and are interconnected, the third horizontal channel and the fourth horizontal channel both are parallel to ta radial cross-section of the process chamber, and the two form an angle; a gas outlet of the third horizontal channel is a gas outlet of the gas mixing channel and is connected to the gas mixing chamber, and a gas inlet of the fourth horizonal channel is located on a side of the third gas inlet block; the connection branch includes a sixth horizontal channel formed in the third gas inlet block and a seventh horizontal channel formed in the second gas inlet block, the sixth horizontal channel and the seventh horizontal channel are interconnected, and a gas outlet of the sixth horizontal channel is interconnected with the fourth horizontal channel; at least one fifth horizontal channel is formed in both the second gas inlet block and the third gas inlet block, the fifth horizontal channel is a second gas mixing branch, and a gas inlet of the fifth horizontal channel is a gas outlet of the gas mixing channel; and a gas outlet of the fifth horizontal channel formed in the third gas inlet block is connected to sixth horizontal channel, and a gas outlet of the fifth horizontal channel formed in the second gas inlet block is connected to the seventh horizontal channel.

In some embodiments, the temperature control component includes a heating component and a first temperature measuring component, the heating component and the first temperature measuring component are disposed in each of the first gas inlet block, the second gas inlet block, and the third gas inlet block, and the first temperature measuring component is electrically connected to the heating component; and the first temperature measuring component is used to detect temperatures of the first gas inlet block, the second gas inlet block, and the third gas inlet block, and control heating power of the heating component according to the temperature thereof.

In some embodiments, the temperature control component further includes a second temperature measuring component, and the second temperature control component is disposed in each of the first gas inlet block, the second gas inlet block, and the third gas inlet block for detecting and displaying temperatures of the first gas inlet block, the second gas inlet block, and the third gas inlet block.

In some embodiments, each connection assembly includes a connection piece and a valve, one end of the connection piece is hermetically connected to a gas inlet of the gas mixing channel, the other end of the connection piece is hermetically connected to the valve, and the valve is used to connect to a process gas supply source, and selectively connect or disconnect between the gas mixing channel and the process gas supply source.

In some embodiments, each connection assembly also includes a pressing member and a sealing joint, the pressing member includes two semi-annular pressing sub-members, the two pressing sub-members butt together to form a closed ring surrounding an outer circumference of the connection piece, and is connected to the gas inlet block assembly for pressing the connection piece on the gas inlet block assembly, and the connection piece is hermetically connected to the valve through the sealing joint.

Another aspect of the present disclosure provides a semiconductor process device. The semiconductor process device includes a process chamber and a disclosed gas inlet apparatus.

The embodiments of the present disclosure have at least the following beneficial effects.

The gas inlet apparatus of the semiconductor process device provided by the embodiments of the present disclosure includes the gas inlet block assembly and the connection assembly made of corrosion-resistant materials. Process gases provided by multiple process gas supply sources enter through multiple connecting assemblies respectively. In the gas mixing channel in the gas inlet block assembly, the process gases are mixed in the gas mixing chamber and then enter the process chamber through the gas transport channel. In addition, because the process gases always flow in the channel formed by the anti-corrosion material, such that corrosion can be prevented at the positions where the gas inlet apparatus is in contact with the reaction gas. Thus, the present disclosure can be applied to processes that require the introduction of corrosive reaction gases (e.g., hydrogen fluoride), such as ammonia-hydrogen fluoride dry etching processes, thereby improving the applicability and scope of the embodiments of the present disclosure. Further, because the corrosion can be prevented at the positions where the gas inlet apparatus is in contact with the reaction gas, the present disclosure can avoid the generation of contaminants due to pipe corrosion, thereby satisfying the particle index requirements on the wafer surface, and substantially improving the wafer yield.

Additional aspects and advantages of the invention will be set forth in part in the description which follows, and will be obvious from the description, or may be learned by practice of the present disclosure.

### BRIEF DESCRIPTION OF THE DRAWINGS

To more clearly illustrate the technical solution of the present disclosure, the accompanying drawings used in the description of the disclosed embodiments are briefly described below. The drawings described below are merely some embodiments of the present disclosure. Other drawings may be derived from such drawings by a person with ordinary skill in the art without creative efforts and may be encompassed in the present disclosure.

FIG. 1 is a schematic longitudinal cross-sectional view of an exemplary gas inlet apparatus coupled in a reaction chamber according to some embodiments of the present disclosure;

FIG. 2 is a schematic lateral cross-sectional view of an exemplary gas inlet apparatus coupled in a reaction chamber according to some embodiments of the present disclosure;

FIG. 3A is a schematic front view of a first gas inlet block according to some embodiments of the present disclosure;

FIG. 3B is a schematic left view of the first gas inlet block according to some embodiments of the present disclosure;

FIG. 3C is a schematic longitudinal view of the first gas inlet block according to some embodiments of the present disclosure;

FIG. 3D is a schematic top view of the first gas inlet block according to some embodiments of the present disclosure;

FIG. 4A is a schematic front view of a second gas inlet block according to some embodiments of the present disclosure;

FIG. 4B is a schematic right view of the second gas inlet block according to some embodiments of the present disclosure;

FIG. 4C is a schematic left view of the second gas inlet block according to some embodiments of the present disclosure;

FIG. 4D is a schematic lateral view of the second gas inlet block according to some embodiments of the present disclosure;

FIG. 5A is a schematic front view of a third gas inlet block according to some embodiments of the present disclosure;

FIG. 5B is a schematic left view of the third gas inlet block according to some embodiments of the present disclosure;

FIG. 5C is a schematic right view of the third gas inlet block according to some embodiments of the present disclosure;

FIG. 5D is a schematic lateral view of the third gas inlet block according to some embodiments of the present disclosure;

FIG. 6A is a schematic top view of an exemplary connection assembly according to some embodiments of the present disclosure;

FIG. 6B is a schematic longitudinal view of an exemplary connection assembly according to some embodiments of the present disclosure; and

FIG. 6C is a schematic three-dimensional (3D) diagram of an exemplary clamp assembly according to some embodiments of the present disclosure.

### DETAILED DESCRIPTION OF THE EMBODIMENTS

The present disclosure is described in detail below, and examples of embodiments of the present disclosure are shown in the accompanying drawings. Same or similar reference numerals throughout represent the same or similar components or components with the same or similar functions. In addition, detailed descriptions of known technologies are omitted if they are unnecessary to illustrate the features of the present disclosure. The embodiments described below with reference to the drawings are exemplary and are merely used to explain the present disclosure and cannot be construed as limiting the present disclosure.

Those skilled in the art understood that, unless otherwise defined, all terms (including technical terms and scientific terms) used herein have the same meanings as commonly understood by one of ordinary skill in the art to which the present disclosure belongs. It should also be understood that terms, such as those defined in general dictionaries, are to be understood to have meanings consistent with their meaning in the context of the prior art, and are not to be used in an idealistic or overly descriptive manner unless specifically defined herein to explain their formal meaning.

In the semiconductor process devices of the prior art, the gas inlet apparatus generally includes a mixing pipe structure, a mixing chamber, a gas inlet pipe, and a gas inlet flange made of stainless steel. The mixing pipe structure is connected to the mixing chamber, and the mixing chamber is connected to an upper cover of a process chamber through the gas inlet pipe and gas inlet flange. In practical applications, process gases (such as reaction gases and dilution gases) provided by multiple process gas supply sources enter the mixing chamber through the mixing pipeline structure for mixing, and then are introduced into the process chamber through the air inlet pipe and the air inlet flange. Certain processes require the introduction of corrosive reactive gases, such as hydrogen fluoride. The corrosive reactive gases will cause corrosion to stainless steel pipelines, especially an upper cover pipeline, which is often opened to expose to atmosphere. Water vapor may be attached to an inner wall of the upper cover pipeline, may strengthen the hydrogen fluoride to corrode the stainless steel pipelines, and may cause the inner wall of the stainless steel pipelines to be corroded and blackened, thereby reducing smoothness of the inner wall of the stainless steel pipelines, and further reducing corrosion resistance to hydrogen fluoride. The iron (Fe) particles corroded from the stainless steel pipelines may enter the process chamber and fall onto the wafer. It is difficult to remove the iron particles on a wafer surface, causing the particle index on the wafer surface to exceed a standard threshold, thus significantly reducing the wafer yield.

The technical solution of the present disclosure and how the technical solution of the present disclosure solves the above technical problems will be described in detail below with specific embodiments.

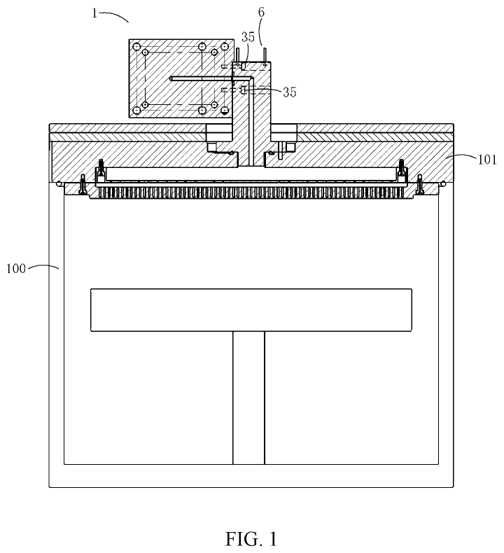

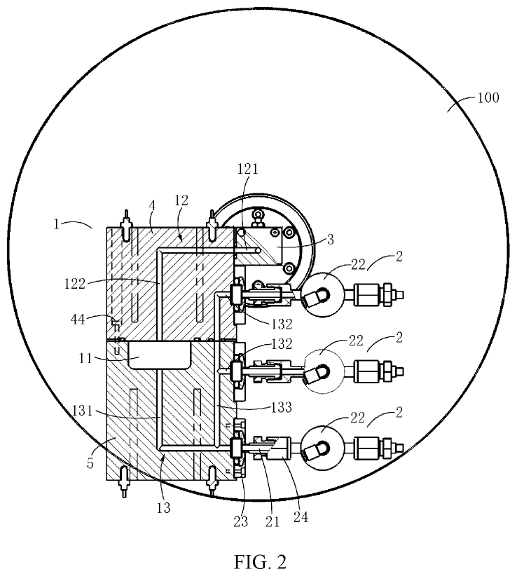

The present disclosure provides a gas inlet apparatus for a semiconductor process device. The gas inlet apparatus is disposed on the top of a process chamber of the semiconductor process device and is used to input process gases into the process chamber. A structural schematic diagram of the gas inlet apparatus is shown in FIG. 1 and FIG. 2. As shown in FIG. 1 and FIG. 2, the gas inlet apparatus includes: a gas inlet block assembly 1 and a connection assembly 2. The gas inlet block assembly 1 and the connection assembly 2 are made of corrosion-resistant materials. In practical applications, appropriate anti-corrosion materials can be selected according to the type of process gas that is passed in. Corrosion-resistant material. For example, for a hydrogen fluoride gas, the corrosion-resistant material used in the gas inlet block assembly 1 may include aluminum. Because the aluminum fluoride (AlF₃) generated from reaction of aluminum material and hydrogen fluoride is very dense, it can effectively solve the problem of hydrogen fluoride corrosion. Because aluminum material is simple to process and has low processing cost and short processing cycle, the gas inlet block assembly 1 that is made of aluminum material can not only prevent hydrogen fluoride from corroding the gas intake apparatus, but also significantly reduce application and maintenance costs of the embodiments of the present disclosure. The corrosion-resistant material used in the connection assembly 2 may include Hastelloy. Hastelloy can not only resist hydrogen fluoride corrosion, thereby avoiding contamination in the process chamber 100, but also substantially improve the strength of the connection assembly 2 because both are made of Hastelloy, thereby substantially reducing failure rate and extending service life of the embodiments of the present disclosure. In practical applications, for hydrogen fluoride, other anti-corrosion materials may also be used. For other corrosive gases, aluminum, Hastelloy, or other anti-corrosion materials may also be used, as long as they can prevent or resist corrosion at the position where the gas intake apparatus is exposed to the reaction gases. No particular limitation is imposed in the embodiments of the present disclosure.

The gas inlet block assembly 1 is connected to an upper cover 101 of the process chamber 100. The connection is a sealed connection. The gas inlet block assembly 1 includes a gas mixing chamber 11, a gas transport channel 12, and a gas mixing channel 13. A gas inlet of the gas transport channel 12 is connected to the gas mixing chamber 11, and a gas outlet of the gas transport channel 12 is connected to the process chamber 100. The gas mixing channel 13 includes a plurality of gas inlets, which are all formed on an outer surface of the gas inlet block assembly 1. A gas outlet of the air mixing channel 13 is connected to the gas mixing chamber 11. A plurality of connection components 2 are arranged on the gas inlet block assembly 1, and the plurality of connection components 2 are connected to the plurality of gas inlets of the gas mixing channel 13 in a one-to-one correspondence. The plurality of connection components 2 are used to connect a plurality of process gases supply sources in a one-to-one correspondence. Each connection assembly 2 is used to selectively introduce or stop a process gas into the gas mixing channel 13.

As shown in FIG. 1 and FIG. 2, the semiconductor process device may perform an ammonia-hydrogen fluoride dry etching process. However, the specific process type performed by the semiconductor process device is limited by the embodiments of the present disclosure. Those skilled in the art can make adjustments according to the actual situation. For example, the gas inlet block assembly 1 maybe a three-dimensional (3D) structure made of a material that is resistant to hydrogen fluoride corrosion. The gas inlet block assembly 1 is hermetically connected to the upper cover 101 of the process chamber 100 through sealing rings and bolts. The gas inlet block assembly 1 is used for mixing a variety of process gases (such as reaction gas and dilution gas) and supplying them to the process chamber 100. The gas mixing chamber 11, the gas transport channel 12, and the gas mixing channel 13 are formed in the gas inlet block assembly 1.

In some embodiments, the gas transport channel 12 may be, for example, a hole formed in the gas inlet block assembly 1. The gas inlet of the gas transport channel 12 is connected to the gas mixing chamber 11, and the gas outlet of the gas transport channel 12 is connected to the process chamber 100.

In some embodiments, the gas mixing chamber 11 may be a cavity formed in the gas inlet block assembly 1. The gas mixing chamber 11 is used to mix a variety of process gases (such as reaction gas and dilution gas) and then supply them to the process chamber 100 through the gas transport channel 12.

In some embodiments, the gas mixing channel 13 may be a hole formed in the gas inlet block assembly 1. A plurality of gas inlets of the gas mixing channel 13 are formed on an outer surface of the gas inlet block assembly 1. A gas outlet of the gas mixing channel 13 is connected to the gas mixing chamber 11 and is used to supply a variety of process gases (such as reaction gas and dilution gas) to the gas mixing chamber 11.

In some embodiments, the plurality of connection components 2 can all be made of materials resistant to hydrogen fluoride corrosion, and their materials may be the same or different. The plurality of connection components 2 are disposed on the gas inlet block assembly 1 and are hermetically connected to the plurality of gas inlets of the gas mixing channel 13, respectively. The plurality of connection components 2 are used to connect to multiple process gas supply sources respectively to supply a variety of process gases (such as reaction gas and dilution gas) to the gas mixing chamber 11 through the gas mixing channel 13.

In the embodiments of the present disclosure, by using the gas inlet block assembly and the plurality of connection components made of materials resistant to hydrogen fluoride corrosion, a variety of process gases (such as reaction gas and dilution gas) provided by multiple process gas supply sources enter the gas mixing channel of the gas inlet block assembly through the plurality of connection components, are mixed in the gas mixing chamber, and enter the process chamber through the gas transport channel. In addition, because the process gases always flow in the channels formed by anti-corrosion materials, corrosion can be prevented at the positions where the gas inlet apparatus contacts with the reaction gases. Thus, the present disclosure can be applied to processes that require the introduction of corrosive reaction gases (e.g., hydrogen fluoride), such as ammonia-hydrogen fluoride dry etching processes, which can improve applicability and scope of the embodiments of the present disclosure. Further, because corrosion can be prevented at the positions where the gas inlet apparatus contacts with the reaction gas, contaminants can be prevented from being generated due to pipeline corrosion, thereby satisfying the particle index requirement on the wafer surface, and substantially improving the wafer yield.

It should be noted that the embodiments of the present disclosure do not limit the specific structure of the gas inlet block assembly 1. For example, the gas inlet block assembly 1 may be a tubular structure. The embodiments of the present disclosure are not limited thereto, and those skilled in the art can make adjustments according to the actual situations.

In some embodiments, as shown in FIG. 1 and FIG. 2, the gas inlet block assembly 1 includes a first gas inlet block 3, a second gas inlet block 4, and a third gas inlet block 5 that are sealed and connected in sequence. The first gas inlet block 3 is hermetically connected to the upper cover 101 of the process chamber 100. The gas transport channel 12 is formed in the first gas inlet block 3 and the second gas inlet block 4, and the gas mixing chamber 11 is formed between the second gas inlet block 4 and the third gas inlet block 5. The gas mixture passage 13 is formed in the second gas inlet block 4 and the third gas inlet block 5.

As shown in FIG. 1 and FIG. 2, the first gas inlet block 3, the second gas inlet block 4, and the third gas inlet block 5 are sealed and connected in sequence. The first gas inlet block 3 is connected to the upper cover 101 of the process chamber 100. The gas transport channel 12 may be formed in the first gas inlet block 3 and the second gas inlet block 4. The gas mixing chamber 11 may be formed between the second gas inlet block 4 and the third gas inlet block 5. The gas mixing channel 13 may be formed in the second gas inlet block 4 and the third gas inlet block 5. By adopting the above design, the present disclosure not only has simple design and processing, but also has better quality control and lower cost, thereby substantially reducing the application and manufacturing costs.

It should be noted that the embodiments of the present application do not limit the number of gas inlet blocks included in the gas inlet block assembly 1. For example, the gas inlet block assembly 1 may include less than three or more than three gas intake blocks. In addition, the present disclosure does not limit the specific positions of the gas mixing chamber 11, the gas transport channel 12, and the gas mixing channel 13. For example, the gas mixing channel 13 may be formed only in the third gas inlet block 5. The present disclosure is not limited thereto, and those skilled in the art can make adjustments according to the actual situations.

In some embodiments, as shown in FIG. 1 and FIG. 2, the gas inlet apparatus also includes a temperature control component 6. The temperature control component 6 may be disposed in the first gas inlet block 3, the second gas inlet block 4, and the third gas inlet block 5, and is used to detect and control temperatures of the first gas inlet block 3, the second gas inlet block 4, and the third gas inlet block 5. For example, the first gas inlet block 3, the second gas inlet block 4, and the third gas inlet block 5, all adopt block structures made of aluminum, and the gas mixing chamber 11, the gas transport channel 12, and the gas mixing channel 13 are all formed in three gas inlet blocks. Thus, the temperature control component 6 can be set inside each gas inlet block without using custom-made heating belts of specific shapes in the existing technology, thereby substantially saving processing and manufacturing costs, and substantially improving the economic benefit of the present disclosure.

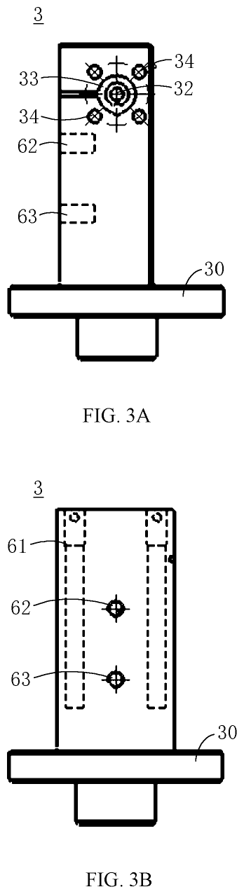

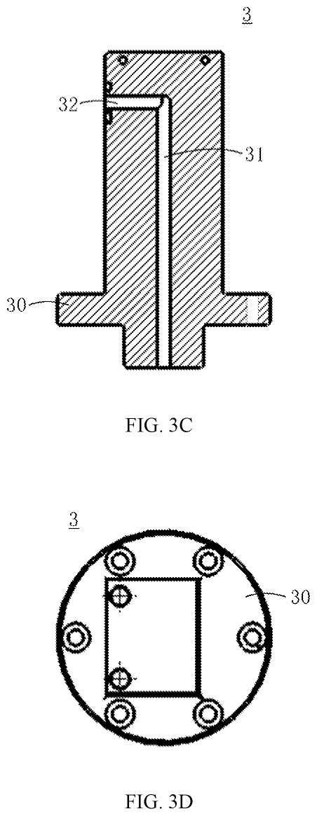

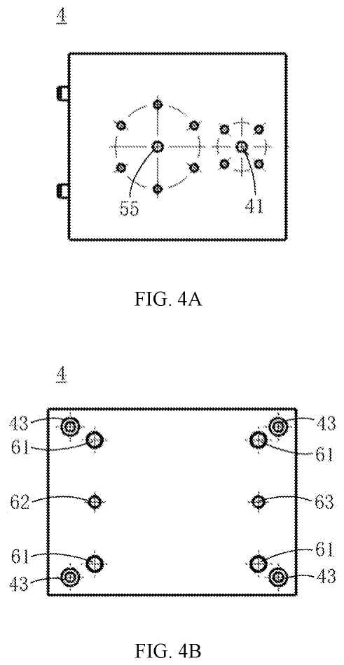

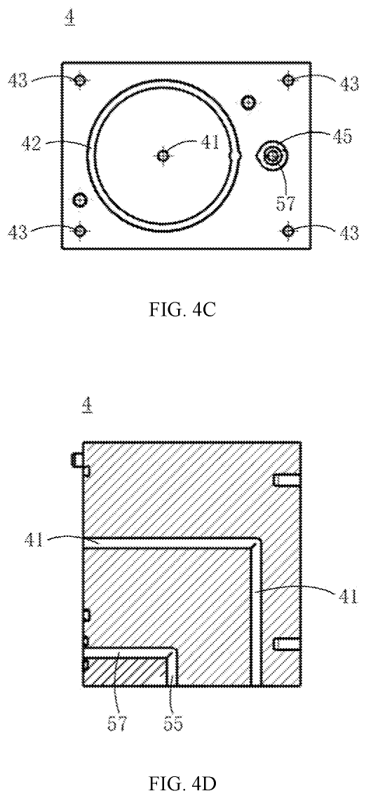

In some embodiments, as shown in FIGS. 1 to 4D, the gas transport channel 12 includes a first gas transport branch 121 and a second gas transport branch 122. The first gas transport branch 121 includes a first vertical channel 31 and a first horizontal channel 32 that are interconnected in the first gas inlet block 3. The first vertical channel 31 is arranged to extend along an axial direction of the process chamber 100 (for example, a length direction of the first gas inlet block 3 in FIG. 3C). The first horizontal channel 32 is arranged to extend along a radial direction of the process chamber 100 (for example, a direction perpendicular to the length direction of the first gas inlet block 3 in FIG. 3C). A gas outlet of the first vertical channel 31 is connected to the process chamber 100. A gas inlet of the first horizontal channel 32 is connected to the second gas transport branch 122. The second gas transport branch 122 includes two interconnected second horizontal channels 41 formed in the second gas inlet block 4. The two second horizontal channel 41 are both parallel to a radial cross-section of the process chamber 100 (i.e., parallel to the radial cross-section of the second gas inlet block 4 in FIG. 4D), and the two are forming an angle. A gas outlet of one of the two second horizontal channels 41 is connected to a gas inlet of the first horizontal channel 32. A gas inlet of the other second horizontal channel 41 is connected to the gas mixing chamber 11.

As shown in FIGS. 1 to 4D, the first gas transport branch 121 is formed in the first gas inlet block 3, and the second gas transport branch 122 is formed in the second gas inlet block 4, such that the embodiments of the present disclosure can have a simple and easy-to-process structure. Thus, the application and manufacturing costs are significantly reduced. In some embodiments, the first gas inlet block 3 may have a rectangular parallelepiped structure, and the bottom thereof is integrally formed with a flange structure 30. The first gas inlet block 3 may be connected to the upper cover 101 of the process chamber 100 through the flange structure 30 at the bottom. For example, fasteners and sealing rings may be used for sealed connection. However, the specific sealing connection is not limited by the embodiments of the present disclosure. The first vertical channel 31 extends along the length direction of the first gas inlet block 3. That is, the first vertical channel 31 is arranged to extend along the axial direction of the process chamber 100 (e.g., the length direction of the first gas inlet block 3 in FIG. 3C). The first horizontal channel 32 may be disposed at the top of the first gas inlet block 3. The first horizontal channel 32 may be arranged to extend along the radial direction of the process chamber 100 (e.g., a direction perpendicular to the length direction of the first gas inlet block 3 in FIG. 3C, such as the horizontal direction). The first horizontal channel 32 is vertically connected to the first vertical channel 31. The first vertical channel 31 and the first horizontal channel 32 together form the first gas transport branch 121. The first horizontal channel 32 is configured to connect to the second gas transport branch 122 in the second gas inlet block 4, such that the second gas inlet block 4 can be disposed on one side of the first gas inlet block 3. The embodiments described above not only substantially save space at the top of the process chamber 100, thereby substantially occupying less space, but also make the structural arrangement of the embodiments of the present disclosure reasonable and convenient for layout.

It should be noted that the embodiments of the present disclosure do not limit that the first vertical channel 31 must extend along the vertical direction and the first horizontal channel 32 must extend along the horizontal direction. Those skilled in the art can adjust the arrangements according to the actual situations.

As shown in FIGS. 1 to 4D, the second gas inlet block 4 has a rectangular parallelepiped structure. The two second horizontal channels 41 extend inward from front and left sides of the second gas inlet block 4 respectively. That is, the two second horizontal channels 41 both are arranged to extend in a radial direction of the second gas inlet block 4. The radial direction of the second gas inlet block 4 is arranged to be parallel with a radial direction of the first gas inlet block 3. However, this is not limited by the embodiments of the present disclosure.

In some embodiments, the two second horizontal channels 41 are connected with each other to form the second gas transport branch 122. A front side of the second gas inlet block 4 (i.e., the side shown in FIG. 4A) is arranged to contact with a front side of the first gas inlet block 3 (i.e., the side shown in FIG. 3A), such that one of the two second horizontal channels 41 is connected to the first horizontal channel 32, and the other second horizontal channel 41 is connected to a center position of the gas mixing chamber 11. In the above design, the third gas inlet block 5 is disposed on one side of the second gas inlet block 4, thereby further saving a top space of the process chamber 100.

In some embodiments, the front side of the first gas inlet block 3 includes an annular first sealing groove 33. The first sealing groove 33 is arranged around a gas inlet of the first horizontal channel 32. A sealing ring may be provided in the first sealing groove 33. The first air inlet block 3 is hermetically connected to the second gas inlet block 4 through the first sealing groove 33 and the sealing ring, thereby achieving a sealed connection between the first gas transport branch 121 and the second gas transport branch 122.

In some embodiments, the first gas inlet block 3 also includes four first connection holes 34 penetrating in a front-rear direction. The four first connection holes 34 are arranged around the first sealing groove 33. Four first fasteners 35 are correspondingly inserted into the four first connection holes 34, and are connected to four connection holes on the front side of the second gas inlet block 4. However, the specific numbers of the first connection hole 34 and the first fasteners 35 are not limited by the embodiments of the present disclosure. Those skilled in the art can adjust the configurations by themselves according to the actual situations. Because the first sealing groove 33 and the four first connection holes 34 are arranged around the gas inlet of the first horizontal channel 32, the embodiments of the present disclosure provide a simple structure, and also substantially improve a sealing effectiveness of the connection between the first gas transport branch 121 and the second gas transport branch 122. However, how the connection between the first gas inlet block 3 and the second gas inlet block 4 is sealed is not limited by the embodiments of the present disclosure. Those skilled in the art can adjust the configurations by themselves according to the actual situations.

In some embodiments, as shown in FIGS. 1 to 5D, a gas mixing groove 51 is provided on one side of the third gas inlet block 5 (arranged to be opposite to the second gas inlet block 4 and used as a sealing surface). An opening of the gas mixing groove 51 is hermetically connected to the side of the second gas inlet block 4 (arranged to be opposite to the third gas inlet block 5 and used as a sealing surface) to form the gas mixing chamber 11. However, the embodiments of the present disclosure are not limited thereto. In practical applications, the gas mixing groove may also be provided on one side of the second gas inlet block 4 (arranged to be opposite to the third air inlet block 5 and used as a sealing surface). The opening of the gas mixing groove is hermetically connected to one side of the third gas inlet block 5 (arranged to be opposite to the second gas inlet block 4 and used as a sealing surface) to form the gas mixing chamber 11. Alternatively, two gas mixing grooves may be provided on one side of the third gas inlet block 5 (arranged to be opposite to the second gas inlet block 4 and used as a sealing surface) and on one side of the second gas inlet block 4 (arranged to be opposite to the third gas inlet block 5 and used as a sealing surface). The two gas mixing grooves are connected to form the gas mixing chamber 11.

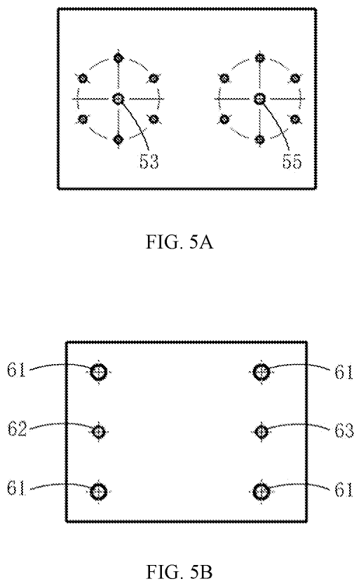

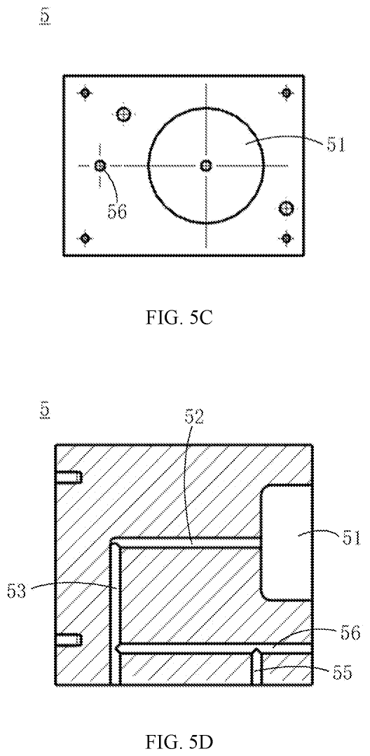

As shown in FIGS. 1 to 5D, the third gas inlet block 5 is a rectangular parallelepiped structure. A circular gas mixing groove 51 is provided on the right side of the third gas inlet block 5 (i.e., the side shown in FIG. 5C). A diameter of the gas mixing groove 51 may be set to 30 to 100 millimeters, which is not limited by the embodiments of the present disclosure. The right side of the third gas inlet block 5 and the left side of the second gas inlet block 4 are arranged in contact with each other, such that the gas mixing groove 51 and the left side of the second gas inlet block 4 are coupled to form the gas mixing chamber 11.

In the above design, the gas mixing groove 51 is provided on the third air inlet block 5 and is coupled with the side of the second gas inlet block 4 to form the gas mixing chamber 11. Thus, turbulence coefficients of the reaction gas and the dilution gas can be substantially improved, thereby substantially improving mixing uniformity of the process gas. The embodiments of the present disclosure have a simple structure, thereby substantially reducing the application and manufacture costs.

Further, an annular second sealing groove 42 is provided on the left side of the second gas inlet block 4 (i.e., the side shown in FIG. 4C), and a sealing ring may be provided in the second sealing groove 42. The second gas inlet block 4 is hermetically connect to the third gas inlet block 5 through the second sealing groove 42 and the sealing ring therein, thereby achieving sealing of the gas mixing chamber 11.

In some embodiments, the second gas inlet block 4 also has four second connection holes 43 penetrating in a left-right direction. The four second connection holes 43 are respectively provided close to four corners of the second gas inlet block 4. Four second fasteners 44 are respectively inserted into the four second connection holes 43 and connected to the connection holes on the right side of the third gas inlet block 5 for pressing the sealing rings in the second sealing groove 42. However, the embodiments of the present disclosure do not limit the specific number and distribution of the second connection holes 43 and the second fasteners 44. Those skilled in the art can adjust the configurations by themselves according to the actual situations. The plurality of second connection holes 43 are respectively located at the corners of the second gas inlet block 4. Thus, the embodiments of the present disclosure have a simple structure, and the connection between the second gas inlet block 4 and the third gas inlet block 5 can be securely sealed. However, the sealing method for the connection between the second gas inlet block 4 and the third gas inlet block 5 is not limited by the embodiments of the present disclosure. Those skilled in the art can adjust the configurations by themselves according to the actual situations.

In some embodiments, as shown in FIGS. 1 to 5D, the gas mixing channel 13 includes a first gas mixing branch 131, a connection branch 133, and a plurality of second gas mixing branches 132. The first gas mixing branch 131 includes a third horizontal channel 52 and a fourth horizontal channel 53 that are interconnected and formed in the third gas inlet block 5. The third horizontal channel 52 and the fourth horizontal channel 53 are both parallel to a radial cross-section of the process chamber 100 (i.e., parallel to the radial cross-section of the third gas inlet block 5 in FIG. 5D), and the two form an angle. The gas outlet of the third horizontal channel 52 is the gas outlet of the gas mixing channel 13 and is connected to the gas mixing chamber 11. The gas inlet of the fourth horizontal channel 53 is located on the side of the third gas inlet block 5. The connection branch 133 includes a sixth horizontal channel 56 formed in the third gas inlet block 5 and a seventh horizontal channel 57 formed in the second gas inlet block 4. The sixth horizontal channel 56 and the seventh horizontal channel 57 are interconnected. A gas outlet of the sixth horizontal channel 56 is interconnected with the fourth horizontal channel 53. At least one fifth horizontal channel 55 is formed in the plurality of second gas inlet blocks 4 and third gas inlet blocks 5. Each fifth horizontal channel 55 is one of the plurality of second gas mixing branches 132. A gas inlet of each fifth horizontal channel 55 is the gas inlet of the gas mixing channel 13. Gas outlets of the at least one fifth horizontal channel 55 formed in the third gas inlet block 5 are all connected to the sixth horizontal channel 56, and the gas outlets of the at least one fifth horizontal channel 55 formed in the second gas inlet block 4 are connected to the seventh horizontal channel 57.

In some other embodiments, as shown in FIGS. 1 to 5D, the gas mixing channel 13 may include a first gas mixing branch 131 and two second gas mixing branches 132. The first gas mixing branch 131 is located in the third gas inlet block 5, and the two second gas mixing branches 132 are formed in the third gas inlet block 5 and the second gas inlet block 4, respectively. Specifically, the first gas mixing branch 131 includes a third horizontal channel 52 and a fourth horizontal channel 53 formed in the third gas inlet block 5. Both the third horizontal channel 52 and the fourth horizontal channel 53 are parallel to the radial cross-section of the process chamber 100 (i.e., parallel to the radial cross-section of the third gas inlet block 5 in FIG. 5D), and the two form an angle. The third horizontal channel 52 and the fourth horizontal channel 53 are connected with each other.

Further, a sixth horizontal channel 56 is provided in the third gas inlet block 5. The sixth horizontal channel 56 is arranged to extend from the right side of the third gas inlet block 5 (i.e., the side shown in FIG. 5C) to the left side until it is connected to the fourth horizontal channel 53. That is, one end of the sixth horizontal channel 56 is arranged side by side with the gas mixing chamber 11, and the other end is vertically connected to the fourth horizontal channel 53. Further, a seventh horizontal channel 57 is provided in the second gas inlet block 4, and the seventh horizontal channel 57 is arranged to extend from the left side of the second air inlet block 4 (i.e., the side shown in FIG. 4C) to the right side. One end of the seventh horizontal channel 57 is connected to one end of the sixth horizontal channel 56 and is coaxially arranged. The other end of the seventh horizontal channel 57 is a closed structure. The sixth horizontal channel 56 and the seventh horizontal channel 57 together form a connection branch 133. In the above design, due to the provision of the connection branch 133, the embodiments of the present disclosure have a simple structure and are easy to process and manufacture, thereby further reducing the processing and manufacturing costs.

In some embodiments, one second gas mixing branch 132 is the fifth horizontal channel 55 formed in the third gas inlet block 5, and another second gas mixing branch 132 is the fifth horizontal channel 55 formed in the second gas inlet block 4. The fifth horizontal channel 55 formed in the third gas inlet block 5 and the sixth horizontal channel 56 are connected to each other. The fifth horizontal channel 55 formed in the second gas inlet block 4 and the seventh horizontal channel 57 are connected to each other. That is, the two second gas mixing branches 132 are formed in the third gas inlet block 5 and the second gas inlet block 4, respectively. However, the embodiments of the present disclosure do not limit the number and distribution of the second gas mixing branches 132. Those skilled in the art can adjust the configurations according to the actual situations.

In some embodiments, the plurality of second gas mixing branches 132 are all connected to the first gas mixing branch 131 through the connection branch 133. However, the embodiments of the present disclosure are not limited thereto. Those skilled in the art can adjust the configurations according to the actual situations.

In some embodiments, the plurality of second gas mixing branches 132 are a plurality of fifth horizontal channels 55 formed in the second gas inlet block 4 and the third gas inlet block 5. The plurality of fifth horizontal channels 55 may be arranged in parallel to the fourth horizontal channel 53, and are arranged to connect to the fourth horizontal channel 53.

In practical applications, the first gas mixing branch 131 may be used to pass in hydrogen fluoride. The two second gas mixing branches 132 may be used to pass in ammonia and nitrogen respectively. That is, the first gas mixing branch 131 and the second gas mixing branch 132 may be used to pass in a reaction gas and a dilution gas, respectively. However, the embodiments of the present disclosure do not limit the specific number of the second gas mixing branches 132 and the specific type of process gas that is passed in each gas mixing branch. Those skilled in the art can adjust the configurations by themselves according to the actual situations. In the above design, the gas inlets of the first gas mixing branch 131 and the plurality of second gas mixing branches 132 are located on a same side of the third gas inlet block 5 and the second gas inlet block 4. Thus, the embodiments of the present disclosure occupy less space, and also have a reasonable structural design, thereby facilitating disassembly, assembly, and maintenance.

Further, a third annular sealing groove 45 is provided on the left side of the second gas inlet block 4 (i.e., the side shown in FIG. 4C). A sealing ring may be provided in the third sealing groove 45. The second air inlet block 4 is hermetically connected to the third gas inlet block 5 through the second sealing groove 42 and the sealing ring, and the seventh horizontal channel 57 and the sixth horizontal channel 56 are sealed. Because the second gas inlet block 4 is connected to the third gas inlet block 5 through the four second fasteners 44, the second gas inlet block 4 and the third gas inlet block 5 are coupled to press the sealing ring in the third sealing groove 45. Because the plurality of second connection holes 43 are respectively located at the corners of the second gas inlet block 4, the embodiments of the present disclosure do not need to provide a separate fastening structure for the third sealing groove 45, thereby reducing the manufacturing cost and simplifying the structure.

It should be noted that the embodiments of the present disclosure do not limit the specific locations of the plurality of second gas mixing branches 132. For example, the plurality of second gas mixing branches 132 may all be formed in the third gas inlet block 5. Thus, the embodiments of the present disclosure are not limited thereto, and those skilled in the art can adjust the configurations by themselves according to the actual situations.

In some embodiments, as shown in FIGS. 1 to 5D, the temperature control component 6 includes a heating component 61 and a first temperature measuring component 62. The heating component 61 and the first temperature measuring component 62 are both disposed in the first gas inlet block 3, the second gas inlet block 4, and the third gas inlet block 5. The first temperature measuring component 62 is electrically connected to the heating component 61. The first temperature measuring component 62 is used to detect temperatures of the first gas inlet block 3, the second gas inlet block 4, and the third gas inlet block 5, and to control heating power of the heating component 61 according to the temperature.

As shown in FIGS. 1 to 5D, the heating component 61 includes a plurality of heating rods. The plurality of heating rods may be respectively disposed in the first gas inlet block 3, the second gas inlet block 4, and the third gas inlet block 5. However, the embodiments of the present disclosure do not limit the number of heating rods included in the heating component 61, and those skilled in the art can adjust the configurations according to the actual situations.

In some embodiments, two 100 W heating rods are inserted into the first gas inlet block 3. Both heating rods are arranged axially parallel to the first gas inlet block 3. Then, two top screws are used to fix the two heating rods in the first gas inlet block 3. Because the second gas inlet block 4 and the third gas inlet block 5 are large in size, four 100 W heating rods are disposed in both of them.

In some embodiments, the four heating rods of the second gas inlet block 4 enter from the right side of the second gas inlet block 4 (i.e., the side shown in FIG. 4B), and are fixedly arranged through top screws. The four heating rods may be arranged close to the four second connection holes 43 such that heating efficiency of the second gas inlet block 4 is higher and more uniform. The four heating rods of the third gas inlet block 5 enter from the left side of the third gas inlet block 5 (i.e., the side shown in FIG. 5B) of the third air inlet block 5), and are fixedly arranged by top screws. The four heating rods may be arranged close to the four corners of the left side of the third gas inlet block 5, such that the heating efficiency of the third gas inlet block 5 is higher and more uniform.

In some embodiments, the first temperature measuring component 62 includes three temperature measuring sensors. The three temperature measuring sensors are respectively disposed in the first gas inlet block 3, the second gas inlet block 4, and the third gas inlet block 5 for detecting the temperatures thereof. Further, the first temperature measuring component 62 may be electrically connected to the heating component 61 provided on the corresponding gas inlet block. For example, the first temperature measuring component 62 and the heating component 61 provided in the first gas inlet block 3 are connected, such that the first temperature measuring component 62 can control the heating power of the heating component 61 according to the temperature of the first gas inlet block 3, thereby controlling the temperature of the first gas inlet block 3. The second gas inlet block 4 and the third gas inlet block 5 have a temperature control principle same as that of the first gas inlet block 3, and the description thereof will be omitted herein. In the above design, the temperatures of the plurality of gas inlet blocks can be controlled separately, thereby improving the temperature uniformity of the plurality of gas inlet blocks.

It should be noted that the embodiments of the present disclosure do not limit the specific connection method of the heating component 61 and the first temperature measuring component 62. For example, the heating component 61 and the first temperature measuring component 62 are both electromechanically connected to a lower-level controller of a semiconductor process device. The lower-level controller controls the temperatures of the plurality of gas inlet blocks either simultaneously or separately. Therefore, the embodiments of the present disclosure are not limited thereto, and those skilled in the art can adjust the configurations by themselves according to the actual situations.

In some embodiments, as shown in FIGS. 1 to 5D, the temperature control component 6 further includes a second temperature measuring component 63. The second temperature measuring component 63 is disposed in the first gas inlet block 3, the second gas inlet block 4, and the third gas inlet block 5 for detecting and displaying the temperatures of the first gas inlet block 3, the second gas inlet block 4, and the third gas inlet block 5. Specifically, the second temperature measuring component 63 also includes three temperature sensors. The three temperature sensors are respectively provided in the first gas inlet block 3, the second gas inlet block 4, and the third gas inlet block 5 for detecting respectively real-time temperatures for the plurality of gas inlet blocks. In the above design, due to the configuration of the second temperature measuring component 63, the temperatures of the plurality of gas inlet blocks can be detected in real time. Thus, the failure of the first temperature measuring component 62 does not prevent detecting the temperatures of the plurality of gas inlet blocks, thereby improving safety and stability of the embodiments of the present disclosure. However, the embodiments of the present disclosure do not limit the number of temperature sensors specifically included in the second temperature measuring component 63, as long as they are arranged corresponding to the number of gas inlet blocks. Therefore, the embodiments of the present disclosure is not limited thereto and those skilled in the art can adjust the configurations themselves according to the actual situations.

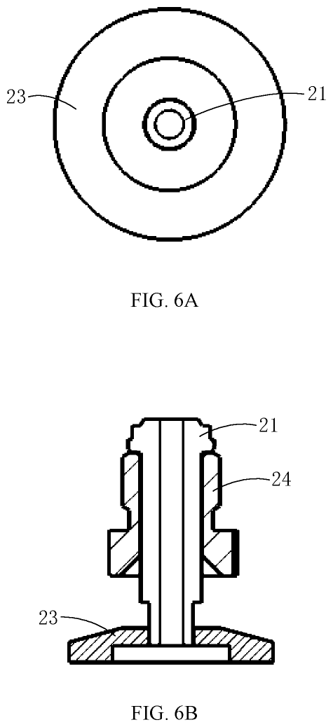

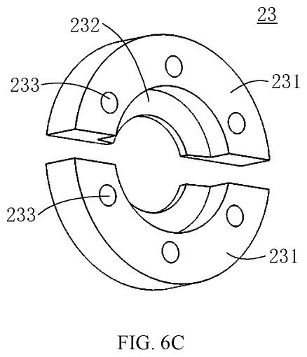

In some embodiments, as shown in FIG. 2 and FIG. 6A to FIG. 6C, each connection assembly 2 includes a connection piece 21 and a valve 22. One end of the connection piece 21 is hermetically connected to the gas inlet of the gas mixing channel 13. The other end of the connection piece 21 is hermetically connected to the valve 22. The valve 22 is used to connect to a process gas supply source, and selectively connect or disconnect between the gas mixing channel 13 and the process gas supply source.

As shown in FIG. 2 and FIG. 6A to FIG. 6C, the connection member 21 has a tubular structure. For hydrogen fluoride, the tubular structure may be made of a material such as Hastelloy. One end of the connection piece 21 is connected to the gas inlet of the gas mixing channel 13. That is, the connection pieces 21 of the plurality of connection components 2 are hermetically connected to the gas inlets of the first gas mixing branch 131 and the plurality of second gas mixing branches 132, respectively. For example, the embodiments of the present disclosure include three connection components 2. The connection pieces 21 of the three connection components 2 are hermetically connected to the gas inlets of one first gas mixing branch 131 and two second gas mixing branches 132, respectively. However, the embodiments of the present disclosure are not limited thereto, as long as the specific number of connection components 2 is configured corresponding to the number of gas inlets of the gas mixing channel 13. The valve 22 may be a pneumatic diaphragm valve made of a material such as Hastelloy alloy. However, the embodiments of the present disclosure do not limit the specific type of the valve 22. The valve 22 is provided on the connection piece 21 and is connected to the process gas supply source. The valve 22 is used to selectively connect or disconnect between the gas mixing channel 13 and the process gas supply source, to selectively supply the process gas to the gas mixing channel 13. In the above design, both the connection piece 21 and the valve 22 are made of a material such as Hastelloy. They can resist hydrogen fluoride corrosion, thereby avoiding contaminants in the process chamber 100. Because both are made of Hastelloy material, the strength of the connection assembly 2 can be substantially improved, thereby significantly reducing the failure rate and extending the service life of the embodiments of the present disclosure.

In some embodiments, as shown in FIG. 2 and FIG. 6A to FIG. 6C, each connection assembly 2 also includes a pressing member 23 and a sealing joint 24. The pressing member 23 includes two semi-annular pressing sub-members 231. The two pressing sub-members 231 butt together to form a closed ring surrounding an outer circumference of the connection piece 21, and is connected to the gas inlet block assembly 1 for pressing the connection piece 21 on the gas inlet block assembly 1. The connection piece 21 is hermetically connected to the valve 22 through the sealing joint 24. Specifically, the pressing member 23 may be an annular structure including the two semi-annular pressing sub-members 231. The two pressing sub-members 231 are coupled together to form a pressing groove 232. The two pressing sub-members 231 are located on both sides of the connection piece 21, respectively, such that a boss at the bottom of the connection piece 21 is located in the pressing groove 232. The two pressing sub-members 231 are each provided with a plurality of through-holes 233 respectively for installing a plurality of bolts. The plurality of bolts penetrate the plurality of through-holes 233 and are connected to the gas inlet block assembly 1 to press the connection piece 21 on the gas inlet block assembly 1 to achieve a sealed connection between the connection piece 21 and the gas inlet of the gas mixture passage 13. The sealing joint 24 may be a vacuum coupling radius seal (VCR) joint, and is disposed between the connection piece 21 and the valve 22 to achieve a sealed connection between the connection piece 21 and the valve 22. In the above design, the process gas does not need to come into contact with the sealing joint 24. Thus, the connection piece 21 and the valve 22 can be sealed while being resistant to hydrogen fluoride corrosion, thereby avoiding contaminants in the process chamber 100 and improving the sealing effect of the connection assembly 2.

Based on the same inventive concept, the present disclosure also provides a semiconductor process device. The semiconductor process device includes a process chamber and the gas inlet apparatus as provided in the above embodiments.

The embodiments of the present disclosure have at least the following beneficial effects.

The gas inlet apparatus of the semiconductor process device provided by the embodiments of the present disclosure includes the gas inlet block assembly and the connection assembly made of corrosion-resistant materials. Process gases provided by multiple process gas supply sources enter through multiple connecting assemblies respectively. In the gas mixing channel in the gas inlet block assembly, the process gases are mixed in the gas mixing chamber and then enter the process chamber through the gas transport channel. In addition, because the process gases always flow in the channel formed by the anti-corrosion material, such that corrosion can be prevented at the positions where the gas inlet apparatus is in contact with the reaction gas. Thus, the present disclosure can be applied to processes that require the introduction of corrosive reaction gases (e.g., hydrogen fluoride), such as ammonia-hydrogen fluoride dry etching processes, thereby improving the applicability and scope of the embodiments of the present disclosure. Further, because the corrosion can be prevented at the positions where the gas inlet apparatus is in contact with the reaction gas, the present disclosure can avoid the generation of contaminants due to pipe corrosion, thereby satisfying the particle index requirements on the wafer surface, and substantially improving the wafer yield.

The above embodiments are only exemplary embodiments to illustrate the principles of the present disclosure. However, the present disclosure is not limited thereto. For those of ordinary skill in the art, various modifications and improvements can be made without departing from the spirit of the present disclosure, and these modifications and improvements are also regarded as the protection scope of the present disclosure.

In the description of the present disclosure, it should be understood that terms such as “center”, “upper”, “lower”, “front”, “back”, “left”, “right”, “vertical”, “horizontal”, “top”, “bottom”, “inner”, “outer”, etc. are used to indicate orientations or positional relationships based on the orientations or positional relationships shown in the drawings. They are merely for the convenience of describing the present disclosure and simplifying the description, and are not intended to indicate or imply that the devices or elements referred to must have a specific orientation, be constructed and operated in a specific orientation. Therefore, they should not be construed as limitations of the present disclosure.

Terms such as “first” and “second” are used for descriptive purposes only and should not be understood as indicating or implying relative importance or implicitly indicating the quantity of indicated technical features. Therefore, features defined as “first” and “second” may explicitly or implicitly include one or more of these features. In the description of the present disclosure, unless otherwise specified, “plurality” means two or more.

In the description of the present disclosure, it should be noted that, unless otherwise clearly stated and limited, terms such as “installation” and “connection” should be understood in a broad sense. For example, the connection may be a fixed connection, a detachable connection, or an integral connection. The connection may be directly connected, or indirectly connected through an intermediary, or the connection may be an internal connection between two components. For those of ordinary skill in the art, the specific meanings of the above terms in the present disclosure can be understood on a case-by-case basis.

In the description of the present disclosure, specific features, structures, materials or characteristics may be combined in any suitable manner in any one or more embodiments or examples.

The above embodiments are only exemplary embodiments adopted to illustrate the principles of the present disclosure, but the present disclosure is not limited thereto. For those of ordinary skill in the art, various modifications and improvements can be made without departing from the spirit and essence of the present disclosure, and these modifications and improvements are also regarded as the protection scope of the present disclosure.

1. A gas inlet apparatus of a semiconductor process device for passing process gases into a process chamber, comprising:
a gas inlet block assembly; and
a connection assembly, both being made of anti-corrosion materials;
wherein:
the gas inlet block assembly is hermetically connected to an upper cover of the process chamber, a gas mixing chamber, a gas transport channel, and a gas mixing channel are formed in the gas inlet lock assembly, a gas inlet of the gas transport channel is connected to the gas mixing chamber, and a gas outlet of the gas transport channel is connected to the process chamber;
the gas mixing channel includes a plurality of gas inlets being formed on an outer surface of the gas inlet block assembly, and a gas outlet of the gas mixing channel is connected to the gas mixing chamber; and
the connection assembly includes a plurality of connection assemblies disposed on the gas inlet block assembly, the plurality of connection assemblies are connected to the plurality of gas inlets of the gas mixing channel in a one-to-one correspondence, the plurality of connection assemblies are used to connect to a plurality of process gas supply sources in a one-to-one correspondence, and each connection assembly is used to selectively introduce or stop the process gases into the gas mixing channel.

2. The gas inlet apparatus according to claim 1, wherein:
the process gases include hydrogen fluoride;
the gas inlet block assembly is made of anti-corrosion materials including aluminum; and
the connection assembly is made of anti-corrosion materials including Hastelloy alloy.

3. The gas inlet apparatus according to claim 1, wherein:
the gas inlet block assembly includes a first gas inlet block, a second gas inlet block, and a third gas inlet block that are hermetically connected in sequence, and the first gas inlet block is hermetically connected to the upper cover of the process chamber;
the gas transport channel is formed in the first gas inlet block and the second gas inlet block, and the gas mixing chamber is formed between the second gas inlet block and the third gas inlet block; and
the gas mixing channel is formed in the second gas inlet block and the third gas inlet block.

4. The gas inlet apparatus according to claim 3, further comprising a temperature control component, wherein:
the temperature control component is disposed in the first gas inlet block, the second gas inlet block, and the third gas inlet block for detecting temperatures of the first gas inlet block, the second gas inlet block, and the third gas inlet block.

5. The gas inlet apparatus according to claim 3, wherein:
the gas transport channel includes a first gas transport branch and a second gas transport branch;
the first gas transport branch includes a first vertical channel and a first horizontal channel that are formed in the first gas inlet block and are interconnected, the first vertical channel is arranged to extend in an axial direction of the process chamber, and the first horizontal channel is arranged to extend in a radial direction of the process chamber;
a gas outlet of the first vertical channel is connected to the process chamber, and a gas inlet of the horizontal channel is connected to second gas transport branch; and
the second gas transport branch includes two interconnected second horizontal channels that are formed in the second gas inlet block. The two second horizontal channels both are parallel to a radial cross-section of the process chamber, the two form an angle, a gas outlet of one of the two horizontal channels is connected to a gas inlet of the first horizontal channel, and a gas inlet of the other second horizontal channel is connected to the gas mixing chamber.

6. The gas inlet apparatus according to claim 3, wherein:
a gas mixing groove is configured on at least one of two opposite-facing sealing surfaces of the third gas inlet block and the second gas inlet block to form the gas mixing chamber.

7. The gas inlet apparatus according to claim 3, wherein:
the gas mixing channel includes a first gas mixing branch, a connection branch, and a plurality of second gas mixing branches;
the first gas mixing branch includes a third horizontal channel and a fourth horizontal channel that are formed in the third gas inlet block and are interconnected, the third horizontal channel and the fourth horizontal channel both are parallel to ta radial cross-section of the process chamber, and the two form an angle;
a gas outlet of the third horizontal channel is a gas outlet of the gas mixing channel and is connected to the gas mixing chamber, and a gas inlet of the fourth horizonal channel is located on a side of the third gas inlet block;
the connection branch includes a sixth horizontal channel formed in the third gas inlet block and a seventh horizontal channel formed in the second gas inlet block, the sixth horizontal channel and the seventh horizontal channel are interconnected, and a gas outlet of the sixth horizontal channel is interconnected with the fourth horizontal channel;
at least one fifth horizontal channel is formed in both the second gas inlet block and the third gas inlet block, the fifth horizontal channel is a second gas mixing branch, and a gas inlet of the fifth horizontal channel is a gas outlet of the gas mixing channel; and
a gas outlet of the fifth horizontal channel formed in the third gas inlet block is connected to sixth horizontal channel, and a gas outlet of the fifth horizontal channel formed in the second gas inlet block is connected to the seventh horizontal channel.

8. The gas inlet apparatus according to claim 4, wherein:
the temperature control component includes a heating component and a first temperature measuring component, the heating component and the first temperature measuring component are disposed in each of the first gas inlet block, the second gas inlet block, and the third gas inlet block, and the first temperature measuring component is electrically connected to the heating component; and
the first temperature measuring component is used to detect temperatures of the first gas inlet block, the second gas inlet block, and the third gas inlet block, and control heating power of the heating component according to the temperature thereof.

9. The gas inlet apparatus according to claim 8, wherein:
the temperature control component further includes a second temperature measuring component, and the second temperature measuring component is disposed in each of the first gas inlet block, the second gas inlet block, and the third gas inlet block for detecting and displaying temperatures of the first gas inlet block, the second gas inlet block, and the third gas inlet block.

10. The gas inlet apparatus according to claim 1, wherein:
each connection assembly includes a connection piece and a valve, one end of the connection piece is hermetically connected to a gas inlet of the gas mixing channel, the other end of the connection piece is hermetically connected to the valve, and the valve is used to connect to a process gas supply source, and selectively connect or disconnect between the gas mixing channel and the process gas supply source.

11. The gas inlet apparatus according to claim 10, wherein:
each connection assembly also includes a pressing member and a sealing joint, the pressing member includes two semi-annular pressing sub-members, the two pressing sub-members butt together to form a closed ring surrounding an outer circumference of the connection piece, and is connected to the gas inlet block assembly for pressing the connection piece on the gas inlet block assembly, and the connection piece is hermetically connected to the valve through the sealing joint.

12. A semiconductor process device, comprising a process chamber and a gas inlet apparatus for passing process gases into a process chamber, wherein the gas inlet apparatus comprises:
a gas inlet block assembly; and
a connection assembly, both being made of anti-corrosion materials;
wherein:
the gas inlet block assembly is hermetically connected to an upper cover of the process chamber, a gas mixing chamber, a gas transport channel, and a gas mixing channel are formed in the gas inlet lock assembly, a gas inlet of the gas transport channel is connected to the gas mixing chamber, and a gas outlet of the gas transport channel is connected to the process chamber;
the gas mixing channel includes a plurality of gas inlets being formed on an outer surface of the gas inlet block assembly, and a gas outlet of the gas mixing channel is connected to the gas mixing chamber; and
the connection assembly includes a plurality of connection assemblies disposed on the gas inlet block assembly, the plurality of connection assemblies are connected to the plurality of gas inlets of the gas mixing channel in a one-to-one correspondence, the plurality of connection assemblies are used to connect to a plurality of process gas supply sources in a one-to-one correspondence, and each connection assembly is used to selectively introduce or stop the process gases into the gas mixing channel.

13. The semiconductor process device according to claim 12, wherein:
the process gases include hydrogen fluoride;
the gas inlet block assembly is made of anti-corrosion materials including aluminum; and
the connection assembly is made of anti-corrosion materials including Hastelloy alloy.

14. The semiconductor process device according to claim 12, wherein:
the gas inlet block assembly includes a first gas inlet block, a second gas inlet block, and a third gas inlet block that are hermetically connected in sequence, and the first gas inlet block is hermetically connected to the upper cover of the process chamber;
the gas transport channel is formed in the first gas inlet block and the second gas inlet block, and the gas mixing chamber is formed between the second gas inlet block and the third gas inlet block; and
the gas mixing channel is formed in the second gas inlet block and the third gas inlet block.

15. The semiconductor process device according to claim 14, the gas inlet apparatus further comprising a temperature control component, wherein:
the temperature control component is disposed in the first gas inlet block, the second gas inlet block, and the third gas inlet block for detecting temperatures of the first gas inlet block, the second gas inlet block, and the third gas inlet block.

16. The semiconductor process device according to claim 14, wherein:
the gas transport channel includes a first gas transport branch and a second gas transport branch;
the first gas transport branch includes a first vertical channel and a first horizontal channel that are formed in the first gas inlet block and are interconnected, the first vertical channel is arranged to extend in an axial direction of the process chamber, and the first horizontal channel is arranged to extend in a radial direction of the process chamber;
a gas outlet of the first vertical channel is connected to the process chamber, and a gas inlet of the horizontal channel is connected to second gas transport branch; and
the second gas transport branch includes two interconnected second horizontal channels that are formed in the second gas inlet block. The two second horizontal channels both are parallel to a radial cross-section of the process chamber, the two form an angle, a gas outlet of one of the two horizontal channels is connected to a gas inlet of the first horizontal channel, and a gas inlet of the other second horizontal channel is connected to the gas mixing chamber.

17. The semiconductor process device according to claim 14, wherein:
a gas mixing groove is configured on at least one of two opposite-facing sealing surfaces of the third gas inlet block and the second gas inlet block to form the gas mixing chamber.

18. The semiconductor process device according to claim 14, wherein:
the gas mixing channel includes a first gas mixing branch, a connection branch, and a plurality of second gas mixing branches;
the first gas mixing branch includes a third horizontal channel and a fourth horizontal channel that are formed in the third gas inlet block and are interconnected, the third horizontal channel and the fourth horizontal channel both are parallel to ta radial cross-section of the process chamber, and the two form an angle;
a gas outlet of the third horizontal channel is a gas outlet of the gas mixing channel and is connected to the gas mixing chamber, and a gas inlet of the fourth horizonal channel is located on a side of the third gas inlet block;
the connection branch includes a sixth horizontal channel formed in the third gas inlet block and a seventh horizontal channel formed in the second gas inlet block, the sixth horizontal channel and the seventh horizontal channel are interconnected, and a gas outlet of the sixth horizontal channel is interconnected with the fourth horizontal channel;
at least one fifth horizontal channel is formed in both the second gas inlet block and the third gas inlet block, the fifth horizontal channel is a second gas mixing branch, and a gas inlet of the fifth horizontal channel is a gas outlet of the gas mixing channel; and
a gas outlet of the fifth horizontal channel formed in the third gas inlet block is connected to sixth horizontal channel, and a gas outlet of the fifth horizontal channel formed in the second gas inlet block is connected to the seventh horizontal channel.

19. The semiconductor process device according to claim 15, wherein:
the temperature control component includes a heating component and a first temperature measuring component, the heating component and the first temperature measuring component are disposed in each of the first gas inlet block, the second gas inlet block, and the third gas inlet block, and the first temperature measuring component is electrically connected to the heating component; and
the first temperature measuring component is used to detect temperatures of the first gas inlet block, the second gas inlet block, and the third gas inlet block, and control heating power of the heating component according to the temperature thereof.

20. The semiconductor process device according to claim 19, wherein:
the temperature control component further includes a second temperature measuring component, and the second temperature measuring component is disposed in each of the first gas inlet block, the second gas inlet block, and the third gas inlet block for detecting and displaying temperatures of the first gas inlet block, the second gas inlet block, and the third gas inlet block.
